(19) United States
(12) Patent Application Publication
(10) Pub. No.: US 2025/0256484 A1
(43) Pub. Date: Aug. 14, 2025

(54) POLYMER FILM AND LAMINATE

(71) Applicant: FUJIFILM Corporation, Tokyo (JP)

(72) Inventors: Miyoko SHIBANO, Kanagawa (JP); Yasuyuki SASADA, Kanagawa (JP); Keita TAKAHASHI, Kanagawa (JP); Hiroshi INADA, Kanagawa (JP); Daisuke HAYASHI, Kanagawa (JP); Naoyuki MOROOKA, Kanagawa (JP)

(73) Assignee: FUJIFILM Corporation, Tokyo (JP)

(21) Appl. No.: 19/190,756

(22) Filed: Apr. 27, 2025

Related U.S. Application Data
(63) Continuation of application No. PCT/JP2023/034981, filed on Sep. 26, 2023.

(30) Foreign Application Priority Data
Oct. 31, 2022 (JP) 2022-175011

(51) Int. Cl. B32B 7/025; B32B 15/088; B32B 27/20; B32B 27/34; H05K 1/02

(52) U.S. Cl. CPC B32B 7/025; B32B 15/088; B32B 27/20; B32B 27/34; B32B 2250/02; B32B 2250/03; B32B 2264/107; B32B 2305/55; B32B 2307/204; B32B 2307/7265; B32B 2457/08; H05K 1/0277; H05K 2201/0141

(57) ABSTRACT

A polymer film including: a layer A; and a layer B provided on at least one surface of the layer A, in which the layer A contains a polymer having a dielectric loss tangent of 0.01 or less, the layer B has a moisture permeability of less than 560 g/(m²·day) at a temperature of 80° C. and a relative humidity of 90%, and the layer B has a moisture absorption rate of 2.5% or less at a temperature of 25° C. and a relative humidity of 80%.

### CROSS-REFERENCE TO RELATED APPLICATION

This application is a Continuation of International Application No. PCT/JP2023/034981, filed Sep. 26, 2023, which claims priority to Japanese Patent Application No. 2022-175011 filed Oct. 31, 2022. Each of the above applications is hereby expressly incorporated by reference, in its entirety, into the present application.

### BACKGROUND OF THE INVENTION

### 1. Field of the Invention

The present disclosure relates to a polymer film and a laminate.

### 2. Description of the Related Art

In recent years, frequencies used in a communication equipment tend to be extremely high. In order to suppress transmission loss in a high frequency band, insulating materials used in a circuit board are required to have a lowered relative permittivity and a lowered dielectric loss tangent. A copper-clad laminated plate is suitably used as a member constituting a circuit board, and a polymer film is suitably used for manufacturing the copper-clad laminated plate.

For example, JP2022-126429A describes a polymer film including a layer A; and a layer B provided on at least one surface of the layer A, in which the layer A contains a polymer having a dielectric loss tangent of 0.01 or less, the layer B has a moisture permeability of 100 g/(m²·day) or less at a temperature of 40° C. and a relative humidity of 90%.

JP2003-103708A discloses a multilayer structure comprising a resin outer layer (A) having a moisture permeability (measured under conditions of 40° C. and a relative humidity of 90%) of a value of 40 g/m²/day or more, an interlayer (B) consisting of a thermoplastic polymer capable of forming an optically anisotropic molten phase, and an inner layer (C) consisting of a thermoplastic resin and having a moisture permeability of less than the moisture permeability of the outer layer (A).

### SUMMARY OF THE INVENTION

Typically, a copper-clad laminated plate is manufactured by laminating a copper foil on a surface of a polymer film. In addition, the wiring board is manufactured by superimposing a copper-clad laminated plate and a wiring base material such that a polymer film in the copper-clad laminated plate and the wiring base material are in contact with each other. In a case of manufacturing a wiring board, from the viewpoint of adhesiveness, it is required that the polymer film deforms by following the step formed on the surface of the wiring base material.

On the other hand, in a case where a polymer film having excellent step followability with respect to the wiring base material is used for the copper-clad laminated plate, interlayer peeling may occur in a reflow soldering step performed in a case of mounting an electronic component. Therefore, it has been required to achieve both excellent step followability with respect to the wiring base material and excellent adhesiveness during reflow soldering (that is, excellent heat resistance).

An object to be achieved by an embodiment of the present invention is to provide a polymer film having excellent step followability and excellent heat resistance.

An object to be achieved by another embodiment of the present invention is to provide a laminate using the above-described polymer film.

The means for achieving the above-described objects include the following aspects.

<1>

A polymer film comprising:
a layer A; and
a layer B provided on at least one surface of the layer A,
in which the layer A contains a polymer having a dielectric loss tangent of 0.01 or less,
the layer B has a moisture permeability of less than 560 g/(m²·day) at a temperature of 80° C. and a relative humidity of 90%, and
the layer B has a moisture absorption rate of 2.5% or less at a temperature of 25° C. and a relative humidity of 80%.
   <2>

The polymer film according to <1>, in which the layer B has a moisture permeability of 300 g/(m²·day) or less at a temperature of 80° C. and a relative humidity of 90%.

<3>

The polymer film according to <1> or <2>, in which the polymer film has a moisture absorption rate of 1.0% or less.

<4>

The polymer film according to any one of <1> to <3>, in which the polymer having a dielectric loss tangent of 0.01 or less is a liquid crystal polymer.

<5>

The polymer film according to <4>, in which the liquid crystal polymer contains an aromatic polyester amide.

<6>

The polymer film according to any one of <1> to <5>, in which the layer B contains a polymer having a dielectric loss tangent of 0.01 or less.

<7>

The polymer film according to <6>, in which the polymer having a dielectric loss tangent of 0.01 or less contains a liquid crystal polymer.

<8>

The polymer film according to <7>, in which the liquid crystal polymer contains an aromatic polyester amide.

<9>

The polymer film according to any one of <1> to <8>, in which the layer B contains a thermoplastic resin containing a constitutional unit based on a monomer having an aromatic hydrocarbon group.

<10>

The polymer film according to any one of <1> to <9>, in which the layer B contains a curing agent.

<11>

The polymer film according to <10>, in which the curing agent is a compound having at least one functional group selected from the group consisting of an epoxy group and a maleimide group.

<12>

The polymer film according to any one of <1> to <11>, in which the layer B contains an inorganic filler.

<13>

The polymer film according to <12>, in which the inorganic filler is at least one selected from the group consisting of silica, aluminum hydroxide, and boron nitride.

<14>

The polymer film according to any one of <1> to <13>, further including: a layer C,
in which the layer B, the layer A, and the layer C are provided in this order.
   <15>

The polymer film according to any one of <1> to <14>, in which a ratio of an elastic modulus of the layer A at 160° C. to an elastic modulus of the layer B at 160° C. is 1.2 or more.

<16>

A laminate including: the polymer film according to any one of <1> to <15>; and a metal layer or a metal wire, disposed on at least one surface of the polymer film.

According to an embodiment of the present invention, it is possible to provide a polymer film having excellent step followability and excellent heat resistance.

Further, according to another aspect of the present invention, it is possible to provide a laminate using the above-described polymer film.

### DESCRIPTION OF THE PREFERRED EMBODIMENTS

Hereinafter, the contents of the present disclosure will be described in detail. The description of configuration requirements below is made based on representative embodiments of the present disclosure in some cases, but the present disclosure is not limited to such embodiments.

In the present specification, a numerical range shown using “to” indicates a range including numerical values described before and after “to” as a lower limit value and an upper limit value.

In a numerical range described in a stepwise manner in the present disclosure, an upper limit value or a lower limit value described in one numerical range may be replaced with an upper limit or a lower limit in another numerical range described in a stepwise manner. In addition, in a numerical range described in the present disclosure, an upper limit value or a lower limit value described in the numerical range may be replaced with a value described in an example.

In addition, in a case where substitution or unsubstitution is not noted in regard to the notation of a “group” (atomic group) in the present specification, the “group” includes not only a group that does not have a substituent but also a group having a substituent. For example, the concept of an “alkyl group” includes not only an alkyl group that does not have a substituent (unsubstituted alkyl group) but also an alkyl group having a substituent (substituted alkyl group).

In the present specification, the concept of “(meth)acryl” includes both acryl and methacryl, and the concept of “(meth)acryloyl” includes both acryloyl and methacryloyl.

Further, the term “step” in the present specification indicates not only an independent step but also a step which cannot be clearly distinguished from other steps as long as the intended purpose of the step is achieved.

Furthermore, in the present disclosure, a combination of two or more preferred embodiments is a more preferred embodiment.

In addition, the weight-average molecular weight (Mw) and the number-average molecular weight (Mn) in the present disclosure are molecular weights converted using polystyrene as a standard substance by performing detection with a gel permeation chromatography (GPC) analysis apparatus using TSKgel SuperHM-H (trade name, manufactured by Tosoh Corporation) column, a solvent of pentafluorophenol (PFP) and chloroform at a mass ratio of 1:2, and a differential refractometer, unless otherwise specified.

### [Polymer Film]

The polymer film according to the present disclosure includes a layer A, and a layer B provided on at least one surface of the layer A, in which the layer A contains a polymer having a dielectric loss tangent of 0.01 or less, and the layer B has a moisture permeability of less than 560 g/(m²·day) at a temperature of 80° C. and a relative humidity of 90%. In addition, the polymer film according to the present disclosure has a moisture absorption rate of 2.5% or less at a temperature of 25° C. and a relative humidity of 80%.

As a result of intensive studies, the inventors of the present invention have found that a polymer film having excellent step followability and excellent heat resistance can be provided by adopting the above-described configuration.

The detailed mechanism that brings about the aforementioned effect is unclear, but is assumed to be as below.

In the polymer film according to the present disclosure, the layer B has a moisture permeability of less than 560 g/(m²·day) at a temperature of 80° C. and a relative humidity of 90%. In addition, since the polymer film according to the present disclosure has a moisture absorption rate of 2.5% or less at a temperature of 25° C. and a relative humidity of 80%, the polymer film is less likely to absorb moisture, and interlayer peeling due to heating is less likely to occur. That is, the heat resistance is excellent. In addition, the layer B functions as a level difference-following layer, and thus the step followability is excellent.

On the other hand, JP2022-126429A and JP2003-103708A do not describe the moisture absorption rate at a temperature of 25° C. and a relative humidity of 80%. In addition, JP2003-103708A does not describe the step followability.

### <Layer A>

The polymer film according to the present disclosure has a layer A in which a layer B described later is provided. The layer A contains a polymer having a dielectric loss tangent of 0.01 or less.

The layer A may contain only one kind of polymer having a dielectric loss tangent of 0.01 or less, or may contain two or more kinds thereof.

In the present disclosure, the dielectric loss tangent is measured by the following method.

The dielectric loss tangent is measured by a resonance perturbation method at a frequency of 10 GHz. A 10 GHz cavity resonator (“CP531” manufactured by Kanto Electronic Application & Development Inc.) is connected to a network analyzer (“E8363B” manufactured by Agilent Technology Company), a polymer film is inserted into the cavity resonator, and the dielectric loss tangent is measured from the change in resonance frequency before and after the insertion for 96 hours in an environment of a temperature of 25° C. and a humidity of 60% RH.

From the viewpoint of the dielectric loss tangent of the polymer film, the dielectric loss tangent of the polymer having a dielectric loss tangent of 0.01 or less is preferably 0.005 or less and more preferably more than 0 and 0.003 or less.

Examples of the polymer having a dielectric loss tangent of 0.01 or less include thermoplastic resins such as a liquid crystal polymer, a fluororesin, a polymerized substance of a compound which has a cyclic aliphatic hydrocarbon group and a group having an ethylenically unsaturated bond, polyether ether ketone, polyolefin, polyamide, polyester, polyphenylene sulfide, polyether ketone, polycarbonate, polyethersulfone, polyphenylene ether and a modified product thereof, and polyetherimide; elastomers such as a copolymer of glycidyl methacrylate and polyethylene; and thermosetting resins such as a phenol resin, an epoxy resin, a polyimide, and a cyanate resin.

### —Liquid Crystal Polymer—

From the viewpoint of dielectric loss tangent of the polymer film, the polymer having a dielectric loss tangent of 0.01 or less is preferably a liquid crystal polymer.

The kind of the liquid crystal polymer is not particularly limited, and a known liquid crystal polymer can be used.

In addition, the liquid crystal polymer may be a thermotropic liquid crystal polymer which exhibits liquid crystallinity in a molten state, or may be a lyotropic liquid crystal polymer which exhibits liquid crystallinity in a solution state. In addition, in a case of the thermotropic liquid crystal, it is preferable that the liquid crystal is melted at a temperature of 450° C. or lower.

Examples of the liquid crystal polymer include a liquid crystal polyester, a liquid crystal polyester amide in which an amide bond is introduced into the liquid crystal polyester, a liquid crystal polyester ether in which an ether bond is introduced into the liquid crystal polyester, and a liquid crystal polyester carbonate in which a carbonate bond is introduced into the liquid crystal polyester.

In addition, as the liquid crystal polymer, from the viewpoint of liquid crystallinity, a polymer having an aromatic ring is preferable, and an aromatic polyester or an aromatic polyester amide is more preferable.

Furthermore, the liquid crystal polymer may be a polymer in which an imide bond, a carbodiimide bond, a bond derived from an isocyanate, such as an isocyanurate bond, or the like is further introduced into the aromatic polyester or the aromatic polyester amide.

In addition, it is preferable that the liquid crystal polymer is a fully aromatic liquid crystal polymer formed of only an aromatic compound as a raw material monomer.

Examples of the liquid crystal polymer include the following liquid crystal polymers.
1) a liquid crystal polymer obtained by polycondensing (i) an aromatic hydroxycarboxylic acid, (ii) an aromatic dicarboxylic acid, and (iii) at least one compound selected from the group consisting of an aromatic diol, an aromatic hydroxyamine, and an aromatic diamine.
2) a liquid crystal polymer obtained by polycondensing a plurality of kinds of aromatic hydroxycarboxylic acids.
3) a liquid crystal polymer obtained by polycondensing (i) an aromatic dicarboxylic acid and (ii) at least one compound selected from the group consisting of an aromatic diol, an aromatic hydroxyamine, and an aromatic diamine.
4) a liquid crystal polymer obtained by polycondensing (i) polyester such as polyethylene terephthalate and (ii) an aromatic hydroxycarboxylic acid.

Here, the aromatic hydroxycarboxylic acid, the aromatic dicarboxylic acid, the aromatic diol, the aromatic hydroxyamine, and the aromatic diamine may be each independently replaced with a polycondensable derivative.

A melting point of the liquid crystal polymer is preferably equal to or higher than 250° C., more preferably 250° C. to 350° C., and still more preferably 260° C. to 330° C.

In the present disclosure, the melting point is measured using a differential scanning calorimetry device. For example, the measurement is performed using product name “DSC-60A Plus” (manufactured by Shimadzu Corporation). A temperature increase rate in the measurement is set to 10° C./minute.

The weight-average molecular weight of the liquid crystal polymer is preferably equal to or less than 1,000,000, more preferably 3,000 to 300,000, still more preferably 5,000 to 100,000, and particularly preferably 5,000 to 30,000.

The liquid crystal polymer preferably includes aromatic polyester amide from a viewpoint of further decreasing the dielectric loss tangent. Aromatic polyester amide is resin having at least one aromatic ring and having an ester bond and an amide bond. Among these, from the viewpoint of heat resistance, the aromatic polyester amide is preferably a fully aromatic polyester amide.

Aromatic polyester amide is preferably a crystalline polymer. The polymer film according to the present disclosure preferably contains a crystalline aromatic polyester amide. Aromatic polyester amide included in the film is crystalline, whereby the dielectric loss tangent further decreases.

The crystalline polymer refers to a polymer having a clear endothermic peak, not a stepwise endothermic amount changed, in differential scanning calorimetry (DSC). Specifically, for example, this means that a half-width of an endothermic peak in measuring at a temperature increase rate 10° C./minute is within 10° C. A polymer in which a half-width exceeds 10° C. and a polymer in which a clear endothermic peak is not recognized are distinguished as an amorphous polymer from a crystalline polymer.

Aromatic polyester amide preferably contains a constitutional unit represented by Formula 1, a constitutional unit represented by Formula 2, and a constitutional unit represented by Formula 3.

—O-Ar1-CO— Formula 1

—CO-Ar2—CO— Formula 2

—NH-Ar3-O— Formula 3

In Formula 1 to Formula 3, Ar1, Ar2, and Ar3 each independently represent a phenylene group, a naphthylene group, or a biphenylylene group.

Hereinafter, the constitutional unit represented by Formula 1 and the like are also referred to as “unit 1” and the like.

The unit 1 can be introduced, for example, using aromatic hydroxycarboxylic acid as a raw material.

The unit 2 can be introduced, for example, using aromatic dicarboxylic acid as a raw material.

The unit 3 can be introduced, for example, using aromatic hydroxylamine as a raw material.

Here, the aromatic hydroxycarboxylic acid, the aromatic dicarboxylic acid, the aromatic diol, and the aromatic hydroxylamine may be each independently replaced with a polycondensable derivative.

For example, the aromatic hydroxycarboxylic acid and the aromatic dicarboxylic acid can be replaced with aromatic hydroxycarboxylic acid ester and aromatic dicarboxylic acid ester, by converting a carboxy group into an alkoxycarbonyl group or an aryloxycarbonyl group.

The aromatic hydroxycarboxylic acid and the aromatic dicarboxylic acid can be replaced with aromatic hydroxycarboxylic acid halide and aromatic dicarboxylic acid halide, by converting a carboxy group into a haloformyl group.

The aromatic hydroxycarboxylic acid and the aromatic dicarboxylic acid can be replaced with aromatic hydroxycarboxylic acid anhydride and aromatic dicarboxylic acid anhydride, by converting a carboxy group into an acyloxycarbonyl group.

Examples of a polymerizable derivative of a compound having a hydroxy group, such as an aromatic hydroxycarboxylic acid and an aromatic hydroxyamine, include a derivative (acylated product) obtained by acylating a hydroxy group and converting the acylated group into an acyloxy group.

For example, the aromatic hydroxycarboxylic acid and the aromatic hydroxylamine can be each replaced with an acylated product by acylating a hydroxy group and converting the acylated group into an acyloxy group.

Examples of a polycondensable derivative of the aromatic hydroxylamine include a substance (acylated product) obtained by acylating an amino group to convert the amino group into an acylamino group.

For example, the aromatic hydroxyamine can be replaced with an acylated product by acylating an amino group and converting the acylated group into an acylamino group.

In Formula 1, Ar1 is preferably a p-phenylene group, a 2,6-naphthylene group, or a 4,4′-biphenylylene group, and more preferably a 2,6-naphthylene group.

In a case where Ar1 is a p-phenylene group, the unit 1 is, for example, a constitutional unit derived from p-hydroxybenzoic acid.

In a case where Ar1 is a 2,6-naphthylene group, the unit 1 is, for example, a constitutional unit derived from 6-hydroxy-2-naphthoic acid.

In a case where Ar1 is a 4,4′-biphenylylene group, the unit 1 is, for example, a constitutional unit derived from 4′-hydroxy-4-biphenylcarboxylic acid.

In Formula 2, Ar2 is preferably a p-phenylene group, an m-phenylene group, or a 2,6-naphthylene group, and more preferably an m-phenylene group.

In a case where Ar2 is a p-phenylene group, the unit 2 is, for example, a constitutional unit derived from terephthalic acid.

In a case where Ar2 is an m-phenylene group, the unit 2 is, for example, a constitutional unit derived from isophthalic acid.

In a case where Ar2 is a 2,6-naphthylene group, the unit 2 is, for example, a constitutional unit derived from 2,6-naphthalenedicarboxylic acid.

In Formula 3, Ar3 is preferably a p-phenylene group or a 4,4′-biphenylylene group, and more preferably a p-phenylene group.

In a case where Ar3 is a p-phenylene group, the unit 2 is, for example, a constitutional unit derived from p-aminophenol.

In a case where Ar3 is a 4,4′-biphenylylene group, the unit 2 is, for example, a constitutional unit derived from 4-amino-4′-hydroxybiphenyl.

With respect to the total content of the unit 1, the unit 2, and the unit 3, a content of the unit 1 is preferably 30 mol % or more, a content of the unit 2 is preferably 35% or less, and a content of the unit 3 is preferably 35 mol % or less.

The content of the unit 1 is preferably 30 mol % to 80 mol %, more preferably 30 mol % to 60 mol %, and particularly preferably 30 mol % to 40 mol % with respect to the total content of the unit 1, the unit 2, and the unit 3.

The content of the unit 2 is preferably 10 mol % to 35 mol %, more preferably 20 mol % to 35 mol %, and particularly preferably 30 mol % to 35 mol % with respect to the total content of the unit 1, the unit 2, and the unit 3.

The content of the unit 3 is preferably 10 mol % to 35 mol %, more preferably 20 mol % to 35 mol %, and particularly preferably 30 mol % to 35 mol % with respect to the total content of the unit 1, the unit 2, and the unit 3.

The total content of the constitutional units is a value obtained by totaling a substance amount (mol) of each constitutional unit. The substance amount of each constitutional unit is calculated by dividing a mass of each constitutional unit constituting aromatic polyester amide by a formula weight of each constitutional unit.

In a case where a ratio of the content of the unit 2 to the content of the unit 3 is expressed as [Content of unit 2]/[Content of unit 3] (mol/mol), the ratio is preferably 0.9/1 to 1/0.9, more preferably 0.95/1 to 1/0.95, and still more preferably 0.98/1 to 1/0.98.

Aromatic polyester amide may have two kinds or more of the unit 1 to the unit 3 each independently. Alternatively, aromatic polyester amide may have other constitutional units other than the unit 1 to the unit 3. A content of other constitutional units is preferably 10% by mole or less and more preferably 5% by mole or less with respect to the total content of all constitutional units.

Aromatic polyester amide is preferably produced by subjecting a source monomer corresponding to the constitutional unit constituting the aromatic polyester amide to melt polymerization.

The weight-average molecular weight of aromatic polyester amide is preferably equal to or less than 1,000,000, more preferably 3,000 to 300,000, still more preferably 5,000 to 100,000, and particularly preferably 5,000 to 30,000.

### —Fluororesin—

From the viewpoint of heat resistance and mechanical strength, the polymer having a dielectric loss tangent of 0.01 or less may be a fluororesin.

In the present disclosure, the kind of the fluororesin is not particularly limited, and a known fluororesin can be used.

Examples of the fluororesin include a homopolymer and a copolymer containing a constitutional unit derived from a fluorinated α-olefin monomer, that is, an α-olefin monomer containing at least one fluorine atom. In addition, examples of the fluororesin include a copolymer containing a constitutional unit derived from a fluorinated α-olefin monomer, and a constitutional unit derived from a non-fluorinated ethylenically unsaturated monomer reactive to the fluorinated α-olefin monomer.

Examples of the fluorinated α-olefin monomer include CF₂═CF₂, CHF═CF₂, CH₂═CF₂, CHCl═CHF, CClF═CF₂, CCl₂═CF₂, CClF═CClF, CHF═CCl₂, CH₂═CClF, CCl₂═CClF, CF₃CF═CF₂, CF₃CF═CHF, CF₃CH═CF₂, CF₃CH═CH₂, CHF₂CH═CHF, CF₃CF═CF₂, and perfluoro (alkyl having 2 to 8 carbon atoms) vinyl ether (for example, perfluoromethyl vinyl ether, perfluoropropyl vinyl ether, and perfluorooctyl vinyl ether). Among these, as the fluorinated α-olefin monomer, at least one monomer selected from the group consisting of tetrafluoroethylene (CF₂═CF₂), chlorotrifluoroethylene (CClF═CF₂), (perfluorobutyl)ethylene, vinylidene fluoride (CH₂═CF₂), and hexafluoropropylene (CF₂═CFCF₃) is preferable.

Examples of the non-fluorinated ethylenically unsaturated monomer include ethylene, propylene, butene, and an ethylenically unsaturated aromatic monomer (for example, styrene and α-methylstyrene).

The fluorinated α-olefin monomer may be used alone or in combination of two or more thereof.

In addition, the non-fluorinated ethylenically unsaturated monomer may be used alone or in combination of two or more thereof.

Examples of the fluororesin include polychlorotrifluoroethylene (PCTFE), poly(chlorotrifluoroethylene-propylene), poly(ethylene-tetrafluoroethylene) (ETFE), poly(ethylene-chlorotrifluoroethylene) (ECTFE), poly(hexafluoropropylene), poly(tetrafluoroethylene-ethylene-propylene), poly(tetrafluoroethylene) (PTFE), poly(tetrafluoroethylene-hexafluoropropylene) (FEP), poly(tetrafluoroethylene-propylene) (FEPM), poly(tetrafluoroethylene-perfluoropropylene vinyl ether), poly(tetrafluoroethylene-perfluoroalkyl vinyl ether) (PFA) (for example, poly(tetrafluoroethylene-perfluoropropyl vinyl ether)), polyvinyl fluoride (PVF), polyvinylidene fluoride (PVDF), poly(vinylidene fluoride-chlorotrifluoroethylene), perfluoropolyether, perfluorosulfonic acid, and perfluoropolyoxetane.

The fluororesin may have a constitutional unit derived from fluorinated ethylene or fluorinated propylene.

The fluororesin may be used alone or in combination of two or more thereof.

The fluororesin is preferably FEP, PFA, ETFE, or PTFE.

The FEP is available from Du Pont as the trade name of TEFLON (registered trademark) FEP or from DAIKIN INDUSTRIES, LTD. as the trade name of NEOFLON FEP. The PFA is available from DAIKIN INDUSTRIES, LTD. as the trade name of NEOFLON PFA, from Du Pont as the trade name of TEFLON (registered trademark) PFA, or from Solvay Solexis as the trade name of HYFLON PFA.

The fluororesin more preferably includes PTFE. The PTFE may be a PTFE homopolymer, a partially modified PTFE homopolymer, or a combination including one or both of these. The partially modified PTFE homopolymer preferably contains a constitutional unit derived from a comonomer other than tetrafluoroethylene in an amount of less than 1% by mass based on the total mass of the polymer.

The fluororesin may be a crosslinkable fluoropolymer having a crosslinkable group. The crosslinkable fluoropolymer can be crosslinked by a known crosslinking method in the related art. One of the representative crosslinkable fluoropolymers is a fluoropolymer having (meth)acryloyloxy. For example, the crosslinkable fluoropolymer can be represented by Formula: H₂C═CR′COO—(CH₂)ₙ—R—(CH₂)ₙ—OOCR′═CH₂.

In the formula, R is an oligomer chain having a constitutional unit derived from the fluorinated α-olefin monomer, R′ is H or —CH₃, and n is 1 to 4. R may be a fluorine-based oligomer chain having a constitutional unit derived from tetrafluoroethylene.

In order to initiate a radical crosslinking reaction through the (meth)acryloyloxy group in the fluororesin, by exposing the fluoropolymer having a (meth)acryloyloxy group to a free radical source, a crosslinked fluoropolymer network can be formed. The free radical source is not particularly limited, and suitable examples thereof include a photoradical polymerization initiator and an organic peroxide. Appropriate photoradical polymerization initiators and organic peroxides are well known in the art. The crosslinkable fluoropolymer is commercially available, and examples thereof include Viton B manufactured by Du Pont.

—Polymerized Substance of Compound which has Cyclic Aliphatic Hydrocarbon Group and Group Having Ethylenically Unsaturated Bond—

The polymer having a dielectric loss tangent of 0.01 or less may be a polymerized substance of a compound which has a cyclic aliphatic hydrocarbon group and a group having an ethylenically unsaturated bond.

Examples of the polymerized substance of a compound which has a cyclic aliphatic hydrocarbon group and a group having an ethylenically unsaturated bond include thermoplastic resins having a constitutional unit derived from a cyclic olefin monomer such as norbornene and a polycyclic norbornene-based monomer.

The polymerized substance of a compound which has a cyclic aliphatic hydrocarbon group and a group having an ethylenically unsaturated bond may be a ring-opened polymer of the above-described cyclic olefin, a hydrogenated product of a ring-opened copolymer using two or more cyclic olefins, or an addition polymer of a cyclic olefin and a linear olefin or aromatic compound having an ethylenically unsaturated bond such as a vinyl group. In addition, a polar group may be introduced into the polymerized substance of a compound which has a cyclic aliphatic hydrocarbon group and a group having an ethylenically unsaturated bond.

The polymerized substance of a compound which has a cyclic aliphatic hydrocarbon group and a group having an ethylenically unsaturated bond may be used alone or in combination of two or more thereof.

A ring structure of the cyclic aliphatic hydrocarbon group may be a single ring, a fused ring in which two or more rings are fused, or a crosslinked ring.

Examples of the ring structure of the cyclic aliphatic hydrocarbon group include a cyclopentane ring, a cyclohexane ring, a cyclooctane ring, an isophorone ring, a norbornane ring, and a dicyclopentane ring.

The compound which has a cyclic aliphatic hydrocarbon group and a group having an ethylenically unsaturated bond is not particularly limited, and examples thereof include a (meth)acrylate compound having a cyclic aliphatic hydrocarbon group, a (meth)acrylamide compound having a cyclic aliphatic hydrocarbon group, and a vinyl compound having a cyclic aliphatic hydrocarbon group. Among these, preferred examples thereof include a (meth)acrylate compound having a cyclic aliphatic hydrocarbon group. In addition, the compound which has a cyclic aliphatic hydrocarbon group and a group having an ethylenically unsaturated bond may be a monofunctional ethylenically unsaturated compound or a polyfunctional ethylenically unsaturated compound.

The number of cyclic aliphatic hydrocarbon groups in the compound which has a cyclic aliphatic hydrocarbon group and a group having an ethylenically unsaturated bond may be 1 or more, and may be 2 or more.

It is sufficient that the polymerized substance of a compound which has a cyclic aliphatic hydrocarbon group and a group having an ethylenically unsaturated bond is a polymer obtained by polymerizing at least one compound which has a cyclic aliphatic hydrocarbon group and a group having an ethylenically unsaturated bond, and it may be a polymerized substance of two or more kinds of the compound which has a cyclic aliphatic hydrocarbon group and a group having an ethylenically unsaturated bond or a copolymer with other ethylenically unsaturated compounds having no cyclic aliphatic hydrocarbon group.

In addition, the polymerized substance of a compound which has a cyclic aliphatic hydrocarbon group and a group having an ethylenically unsaturated bond is preferably a cycloolefin polymer.

### —Polyphenylene Ether—

The polymer having a dielectric loss tangent of 0.01 or less may be a polyphenylene ether.

In the polyphenylene ether, from the viewpoint of dielectric loss tangent and heat resistance, the average number of molecular terminal phenolic hydroxyl groups per molecule (the number of terminal hydroxyl groups) is preferably 1 to 5 and more preferably 1.5 to 3.

The number of terminal hydroxyl groups in the polyphenylene ether can be found, for example, from a standard value of a product of the polyphenylene ether. In addition, the number of terminal hydroxyl groups is expressed as, for example, an average value of the number of phenolic hydroxyl groups per molecule of all polyphenylene ethers present in 1 mol of the polyphenylene ether.

The polyphenylene ether may be used alone or in combination of two or more thereof.

Examples of the polyphenylene ether include a polyphenylene ether including 2,6-dimethylphenol and at least one of bifunctional phenol or trifunctional phenol, and poly(2,6-dimethyl-1,4-phenylene oxide). More specifically, the polyphenylene ether is preferably a compound having a structure represented by Formula (PPE).

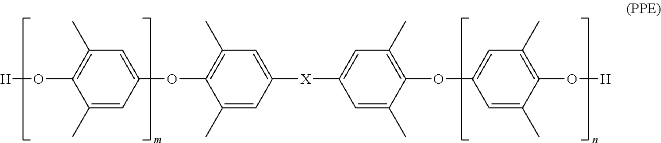

In Formula (PPE), X represents an alkylene group having 1 to 3 carbon atoms or a single bond, m represents an integer of 0 to 20, n represents an integer of 0 to 20, and the sum of m and n represents an integer of 1 to 30.

Examples of the alkylene group in X described above include a dimethylmethylene group.

In a case where heat curing is performed after film formation, from the viewpoint of heat resistance and film-forming property, a weight-average molecular weight (Mw) of the polyphenylene ether is preferably 500 to 5,000 and preferably 500 to 3,000. In addition, in a case where the heat curing is not performed, the weight-average molecular weight (Mw) of the polyphenylene ether is not particularly limited, but is preferably 3,000 to 100,000 and preferably 5,000 to 50,000.

### —Aromatic Polyether Ketone—

The polymer having a dielectric loss tangent of 0.01 or less may be an aromatic polyether ketone.

The aromatic polyether ketone is not particularly limited, and a known aromatic polyether ketone can be used.

The aromatic polyether ketone is preferably a polyether ether ketone.

The polyether ether ketone is one kind of the aromatic polyether ketone, and is a polymer in which bonds are arranged in the order of an ether bond, an ether bond, and a carbonyl bond. It is preferable that the bonds are linked to each other by a divalent aromatic group.

The aromatic polyether ketone may be used alone or in combination of two or more thereof.

Examples of the aromatic polyether ketone include polyether ether ketone (PEEK) having a chemical structure represented by Formula (P1), polyether ketone (PEK) having a chemical structure represented by Formula (P2), polyether ketone ketone (PEKK) having a chemical structure represented by Formula (P3), polyether ether ketone ketone (PEEKK) having a chemical structure represented by Formula (P4), and polyether ketone ether ketone ketone (PEKEKK) having a chemical structure represented by Formula (P5).

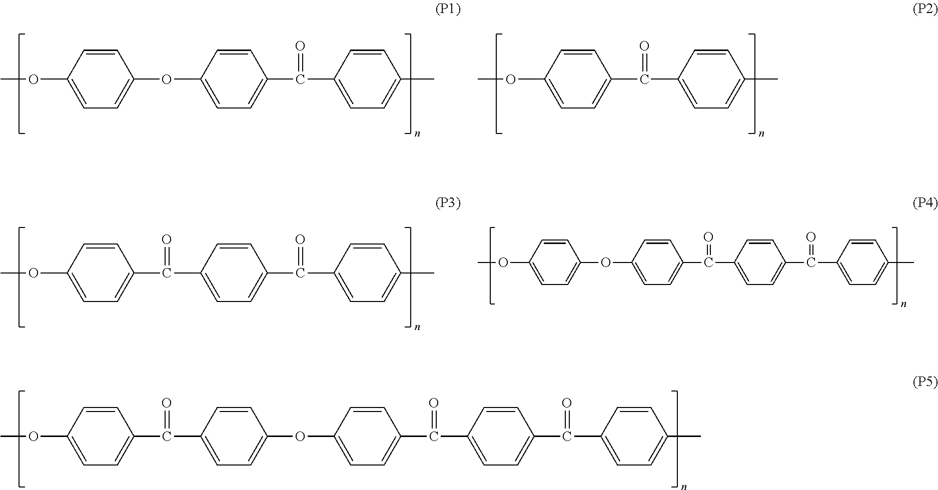

From the viewpoint of mechanical properties, each n of Formulae (P1) to (P5) is preferably 10 or more and more preferably 20 or more. On the other hand, from the viewpoint that the aromatic polyether ketone can be easily produced, n is preferably 5,000 or less and more preferably 1,000 or less. That is, n is preferably 10 to 5,000 and more preferably 20 to 1,000.

From the viewpoint of dielectric loss tangent of the polymer film, the content of the polymer having a dielectric loss tangent of 0.01 or less is preferably 20% by mass or more, more preferably 30% by mass or more, and particularly preferably 50% by mass to 100% by mass with respect to the total mass of the layer A.

The layer A may contain a filler in addition to the polymer having a dielectric loss tangent of 0.01 or less.

### —Filler—

The filler may be particulate or fibrous, and may be an inorganic filler or an organic filler. From the viewpoint of dielectric loss tangent, heat resistance, and step followability of the polymer film, the filler is preferably an organic filler.

As the organic filler, a known organic filler can be used.

Examples of a material of the organic filler include polyethylene, polystyrene, urea-formalin filler, polyester, cellulose, acrylic resin, fluororesin, cured epoxy resin, crosslinked benzoguanamine resin, crosslinked acrylic resin, a liquid crystal polymer, and a material containing two or more kinds of these.

In addition, the organic filler may be fibrous, such as nanofibers, or may be hollow resin particles.

Among these, as the organic filler, from the viewpoint of the dielectric loss tangent, the heat resistance, and the step followability of the polymer film, fluororesin particles, polyester-based resin particles, polyethylene particles, liquid crystal polymer particles, or cellulose-based resin nanofibers are preferable; polytetrafluoroethylene particles, polyethylene particles, or liquid crystal polymer particles are more preferable; and liquid crystal polymer particles are particularly preferable. Here, the liquid crystal polymer particles are not limited, but refer to particles obtained by polymerizing a liquid crystal polymer and crushing the liquid crystal polymer with a crusher or the like to obtain powdery liquid crystal. The liquid crystal polymer particles are preferably smaller than the thickness of each layer.

From the viewpoint of dielectric loss tangent, heat resistance, and step followability of the polymer film, the average particle diameter of the organic filler is preferably 5 nm to 20 μm and more preferably 100 nm to 10 μm.

As the inorganic filler, a known inorganic filler can be used.

Examples of a material of the inorganic filler include BN, Al₂O₃, AlN, TiO₂, SiO₂, barium titanate, strontium titanate, aluminum hydroxide, calcium carbonate, and a material containing two or more of these.

Among these, as the inorganic filler, from the viewpoint of dielectric loss tangent, heat resistance, and step followability of the polymer film, metal oxide particles or fibers are preferable, silica particles, titania particles, or glass fibers are more preferable, and silica particles or glass fibers are particularly preferable.

An average particle diameter of the inorganic filler is preferably approximately 20% to approximately 40% of the thickness of a layer A, and for example, the average particle diameter may be selected from 25%, 30%, or 35% of the thickness of the layer A. In a case where the particles or fibers are flat, the average particle diameter indicates a length in a short side direction.

In addition, from the viewpoint of dielectric loss tangent, heat resistance, and step followability of the polymer film, the average particle diameter of the inorganic filler is preferably 5 nm to 20 μm, more preferably 10 nm to 10 μm, still more preferably 20 nm to 1 μm, and particularly preferably 25 nm to 500 nm.

The layer A may contain only one or two or more kinds of the fillers.

In a case where the layer A contains a filler, from the viewpoint of the dielectric loss tangent, the heat resistance, and the step followability of the polymer film, the content of the filler is preferably 30% by mass to 95% by mass, more preferably 50% by mass to 90% by mass, and particularly preferably 60% by mass to 80% by mass with respect to the total mass of the layer A.

### —Other Additives—

The layer A may contain an additive other than the above-described components.

Known additives can be used as other additives. Specific examples of the other additives include a curing agent, a leveling agent, an antifoaming agent, an antioxidant, an ultraviolet absorbing agent, a flame retardant, and a colorant.

In addition, the layer A may contain, as other additives, a resin other than the polymer having a dielectric loss tangent of 0.01 or less.

Examples of the resin other than the polymer having a dielectric loss tangent of 0.01 or less include thermoplastic resins other than liquid crystal polyester, such as polypropylene, polyamide, polyester other than liquid crystal polyester, polyphenylene sulfide, polyether ketone, polycarbonate, polyethersulfone, polyphenylene ether and a modified product thereof, and polyetherimide; elastomers such as a copolymer of glycidyl methacrylate and polyethylene; and thermosetting resins such as a phenol resin, an epoxy resin, a polyimide resin, and a cyanate resin.

The total content of the other additives in the layer A is preferably 25 parts by mass or less, more preferably 10 parts by mass or less, and still more preferably 5 parts by mass or less with respect to 100 parts by mass of the content of the polymer having a dielectric loss tangent of 0.01 or less.

The average thickness of the layer A is not particularly limited, but from the viewpoint of dielectric loss tangent, heat resistance, and step followability of the polymer film, the average thickness of the layer A is preferably 5 μm to 90 μm, more preferably 10 μm to 70 μm, and particularly preferably 15 μm to 50 μm.

A method for measuring the average thickness of each layer in the polymer film according to the embodiment of the present disclosure is as follows.

The polymer film is cut along a plane perpendicular to a plane direction of the polymer film, thicknesses are measured at five or more points on a cross section thereof, and an average value thereof is defined as the average thickness.

The moisture permeability of the layer A at a temperature of 80° C. and a relative humidity of 90% is not particularly limited, but from the viewpoint of heat resistance, the moisture permeability is preferably less than 560 g/(m²·day), more preferably 300 g/(m²·day) or less, still more preferably 200 g/(m²·day) or less, and particularly preferably 100 g/(m²·day) or less. The lower limit value of the moisture permeability of the layer B is not particularly limited, and is, for example, 0 g/(m²·day).

A method of measuring the moisture permeability will be described later.

### <Layer B>

The polymer film according to the present disclosure includes a layer B on at least one surface of the above-described layer A. The layer B is preferably a surface layer (outermost layer).

The layer B has a moisture permeability of less than 560 g/(m²·day) at a temperature of 80° C. and a relative humidity of 90%. In a case where the moisture permeability of the layer B is less than 560 g/(m²·day), moisture is less likely to enter the polymer laminate under high humidity, and interlayer peeling due to heating is less likely to occur. That is, the heat resistance is excellent.

In order to make the moisture permeability of the layer B less than 560 g/(m²·day), it is preferable to use a known hydrophobic material and/or a material having a small free volume as a main material constituting the layer B. Specific examples of the layer B include a polymer layer having crystallinity, an inorganic sputter film, and a multilayer film of an inorganic sputter film and a sol-gel organic film. In addition, in a case where a polymer material is used as a material constituting the layer B, increasing the degree of crystallinity by a heat treatment, stretching, or the like is effective in making the moisture permeability of the layer B less than 560 g/(m²·day). In addition, it is also effective to add an additive having an effect of reducing the free volume in order to reduce the moisture permeability of the layer B to less than 560 g/(m²·day).

In the present disclosure, the moisture permeability is measured by the following method.

The moisture permeability of the entire polymer film is measured using a polymer film obtained by removing a copper foil of a copper-clad laminated plate with an aqueous solution of ferric chloride, washing the copper foil with pure water, and drying the copper foil.

In addition, the moisture permeability of each layer is measured by the following method. First, one copper foil of the double-sided copper-clad laminated plate is removed with an aqueous solution of ferric chloride, washed with pure water, and then scraped off with a razor. The other copper foil is removed with an aqueous solution of ferric chloride and washed with pure water. The moisture permeability of each layer is measured using a portion obtained by drying. In addition, since the moisture permeability changes depending on the film thickness, the measured moisture permeability is multiplied by the measured film thickness and divided by 50 to obtain the “moisture permeability in a case of being converted to a moisture permeability in a case where the film thickness is 50 μm”.

With reference to a moisture permeability test (cup method) of JIS Z 0208:1976, a film is set in a moisture permeation cup having an inner diameter of 20 mmφ containing calcium chloride, and the moisture permeability can be obtained from a mass change before and after the film is placed in a constant temperature and humidity device at a temperature of 80° C. and a relative humidity of 90% for 24 hours.

From the viewpoint of heat resistance, the moisture permeability of the layer B is preferably 300 g/(m²·day) or less, more preferably 200 g/(m²·day) or less, and still more preferably 100 g/(m²·day) or less. The lower limit value of the moisture permeability of the layer B is not particularly limited, and is, for example, 0 g/(m²·day).

The component contained in the layer B is not particularly limited as long as the moisture permeability can be set to less than 560 g/(m²·day). The layer B preferably contains at least one polymer.

From the viewpoint of dielectric loss tangent of the polymer film and step followability, the layer B preferably contains a thermoplastic resin. The thermoplastic resin may be a thermoplastic elastomer. The elastomer refers to a polymer compound exhibiting elastic deformation. That is, the elastomer corresponds to a polymer compound having a property of being deformed according to an external force in a case where the external force is applied and of being recovered to an original shape in a short time in a case where the external force is removed.

Examples of the thermoplastic resin include a polyurethane resin, a polyester resin, a (meth)acrylic resin, a polystyrene resin, a fluororesin, a polyimide resin, a fluorinated polyimide resin, a polyamide resin, a polyamideimide resin, a polyether imide resin, a cellulose acylate resin, a polyether ether ketone resin, a polycarbonate resin, a polyolefin resin (for example, a polyethylene resin, a polypropylene resin, a resin consisting of a cyclic olefin copolymer, and an alicyclic polyolefin resin), a polyarylate resin, a polyether sulfone resin, a polysulfone resin, a fluorene ring-modified polycarbonate resin, an alicyclic ring-modified polycarbonate resin, and a fluorene ring-modified polyester resin.

The thermoplastic elastomer is not particularly limited, and examples thereof include an elastomer including a constitutional repeating unit derived from styrene (polystyrene-based elastomer), a polyester-based elastomer, a polyolefin-based elastomer, a polyurethane-based elastomer, a polyamide-based elastomer, a polyacryl-based elastomer, a silicone-based elastomer, and a polyimide-based elastomer. The thermoplastic elastomer may be a hydride.

Examples of the polystyrene-based elastomer include a styrene-butadiene-styrene block copolymer (SBS), a styrene-isoprene-styrene block copolymer (SIS), a polystyrene-poly(ethylene-propylene) diblock copolymer (SEP), a polystyrene-poly(ethylene-propylene)-polystyrene triblock copolymer (SEPS), a styrene-ethylene-butylene-styrene block copolymer (SEBS), a polystyrene-poly(ethylene/ethylene-propylene)-polystyrene triblock copolymer (SEEPS), a styrene-isobutylene-styrene block copolymer (SIBS), and hydrides thereof.

Among these, from the viewpoint of dielectric loss tangent, heat resistance, and step followability of the polymer film, the layer B preferably contains a thermoplastic resin containing a constitutional unit derived from a monomer having an aromatic hydrocarbon group, more preferably contains a polystyrene-based elastomer, and more preferably contains a styrene-ethylene-butylene-styrene block copolymer, a styrene-isobutylene-styrene block copolymer, a styrene-ethylene-propylene block copolymer, a styrene-ethylene-propylene-styrene block copolymer, or a styrene-ethylene-ethylene-propylene-styrene copolymer.

The content of the thermoplastic resin is not particularly limited, but from the viewpoint of dielectric loss tangent, heat resistance, and step followability of the polymer film, it is preferably 50% by mass to 100% by mass, and more preferably 60% by mass to 100% by mass with respect to the total mass of the layer B.

In addition, from the viewpoint of the dielectric loss tangent of the film, the layer B preferably contains a polymer having a dielectric loss tangent of 0.01 or less. The preferred aspect of the polymer having a dielectric loss tangent of 0.01 or less is the same as the preferred aspect of the polymer having a dielectric loss tangent of 0.01 or less, which can be contained in the layer A.

Among these, the layer B preferably contains a liquid crystal polymer and more preferably contains aromatic polyester amide.

In a case where the layer B contains a polymer having a dielectric loss tangent of 0.01 or less, the content of the polymer having a dielectric loss tangent of 0.01 or less is not particularly limited, but from the viewpoint of dielectric loss tangent, heat resistance, and step followability of the polymer film, the content of the polymer having a dielectric loss tangent of 0.01 or less is preferably 10% by mass to 100% by mass, more preferably 10% by mass to 70% by mass, and particularly preferably 10% by mass to 60% by mass with respect to the total mass of the layer B.

From the viewpoint of dielectric loss tangent, heat resistance, and step followability of the polymer film, the layer B more preferably contains a filler.

Examples of the filler which can be contained in the layer B include the same ones as those which can be contained in the layer A.

Among these, from the viewpoint of dielectric loss tangent, heat resistance, and step followability of the polymer film, the layer B preferably contains an inorganic filler.

The inorganic filler contained in the layer B is preferably at least one selected from the group consisting of silica, aluminum hydroxide, and boron nitride.

The layer B may contain only one or two or more kinds of the fillers.

From the viewpoint of dielectric loss tangent, heat resistance, and step followability of the polymer film, the content of the filler in the layer B is preferably 10% by mass to 90% by mass, and more preferably 20% by mass to 80% by mass with respect to the total mass of the layer B.

From the viewpoint of step followability, the layer B preferably contains a curing agent.

Examples of the curing agent contained in the layer B include compounds having a maleimide group, an epoxy group, an allyl group, a vinyl group, an oxetanyl group, a cyanate group, a benzoxazine group, and the like. From the viewpoint of moisture permeability, the compound is preferably a compound having at least one functional group selected from the group consisting of an epoxy group and a maleimide group.

The layer B may contain an additive other than those described above.

Preferred aspects of other additives which are used in the layer B are the same as the preferred aspects of other additives which are used in the layer A.

The layer B is preferably a surface layer (outermost layer). The layer B has excellent step followability, and thus has excellent adhesiveness in the bonding to the metal wire.

From the viewpoint of heat resistance and step followability, the average thickness of the layer B is preferably 0.1 μm to 20 μm, more preferably 0.5 μm to 15 μm, still more preferably 1 μm to 10 μm, and particularly preferably 1 μm to 5 μm.

From the viewpoint of heat resistance and step followability, the polymer film according to the present disclosure preferably further includes a layer C in addition to the above-described layer A and the above-described layer B, and more preferably includes the above-described layer B, the above-described layer A, and the above-described layer C in this order.

### <Layer C>

The layer C is preferably an adhesive layer. That is, the layer C is preferably a surface layer (outermost layer).

The moisture permeability of the layer C at a temperature of 80° C. and a relative humidity of 90% is not particularly limited, but from the viewpoint of heat resistance, it is preferably less than 560 g/(m²·day), more preferably 300 g/(m²·day) or less, still more preferably 200 g/(m²·day) or less, and particularly preferably 100 g/(m²·day) or less. The lower limit value of the moisture permeability of the layer B is not particularly limited, and is, for example, 0 g/(m²·day).

From the viewpoint of dielectric loss tangent of the film, the layer C preferably contains at least one polymer.

The preferred aspect of the polymer used in the layer C is the same as the preferred aspect of the polymer having a dielectric loss tangent of 0.01 or less, which is used in the layer A.

The polymer contained in the layer C may be the same as or different from the polymer contained in the layer A or the layer B, but from the viewpoint of adhesiveness between the layer A and the layer C, it is preferable that the polymer contained in the layer C is the same as the polymer contained in the layer A.

In addition, since the layer C is used to bond the metal layer and the layer A, it is preferable that the layer C contains an epoxy resin.

The epoxy resin is preferably a crosslinked product of a polyfunctional epoxy compound. The polyfunctional epoxy compound refers to a compound having two or more epoxy groups. The number of epoxy groups in the polyfunctional epoxy compound is preferably 2 to 4.

In particular, from the viewpoint of dielectric loss tangent of the film and adhesiveness with the metal layer, the layer C preferably contains aromatic polyester amide and an epoxy resin.

The layer C may contain a filler.

Preferred aspects of the filler which is used in the layer C are the same as the preferred aspects of the filler which is used in the layer A.

The layer C may contain an additive other than those described above.

Preferred aspects of other additives which are used in the layer C are the same as the preferred aspects of other additives which are used in the layer A, except as described below.

From the viewpoint of dielectric loss tangent of the film and adhesiveness to the metal, it is preferable that an average thickness of the layer C is smaller than an average thickness of the layer A.

From the viewpoint of dielectric loss tangent of the film and adhesiveness to the metal, a value of T^{A}/T^{C}, which is a ratio of the average thickness T^{A} of the layer A to an average thickness T^{C} of the layer C, is preferably more than 1, more preferably 2 to 100, still more preferably 2.5 to 20, and particularly preferably 3 to 10.

From the viewpoint of dielectric loss tangent of the film and adhesiveness to the metal, a value of T^{B}/T^{C}, which is a ratio of the average thickness T^{B} of the layer B to the average thickness T^{C} of the layer C, is preferably more than 1, more preferably 2 to 100, still more preferably 2.5 to 20, and particularly preferably 3 to 10.

Furthermore, from the viewpoint of dielectric loss tangent of the film and adhesiveness to the metal layer, the average thickness of the layer C is preferably 0.1 μm to 20 μm, more preferably 0.5 μm to 15 μm, still more preferably 1 μm to 10 μm, and particularly preferably 2 μm to 8 μm.

From the viewpoint of strength and electrical characteristics (characteristic impedance) in a case of being laminated with the metal layer, an average thickness of the polymer film according to the embodiment of the present disclosure is preferably 6 μm to 200 μm, more preferably 12 μm to 100 μm, and particularly preferably 20 μm to 80 μm.

The average thickness of the polymer film is measured at optional five sites using an adhesive film thickness meter, for example, an electronic micrometer (product name “KG3001A”, manufactured by Anritsu Corporation), and the average value of the measured values is defined as the average thickness of the polymer film.

<Relationship between layer A and layer B>

From the viewpoint of step followability, a ratio of the elastic modulus of the layer A at 160° C. to the elastic modulus of the layer B at 160° C. is preferably 1.2 or more, more preferably 10 to 1,000, still more preferably 100 to 700, and particularly preferably 200 to 400.

From the viewpoint of strength, the elastic modulus of the layer A at 160° C. is preferably 100 MPa to 2,500 MPa, more preferably 200 MPa to 2,500 MPa, still more preferably 300 MPa to 1,500 MPa, and particularly preferably 500 MPa to 2,500 MPa.

From the viewpoint of step followability, the elastic modulus of the layer B at 160° C. is preferably 100 MPa or less, more preferably 10 MPa or less, still more preferably 0.001 MPa to 10 MPa, and particularly preferably 0.5 MPa to 5 MPa.

In the present disclosure, the elastic modulus is measured by the following method.

First, the polymer film is cut in a cross section with a microtome or the like, and the layer A or the layer B is specified from an image observed with an optical microscope. Next, the elastic modulus of the specified layer A or layer B is measured as an indentation elastic modulus using a nanoindentation method. The indentation elastic modulus is measured by using a microhardness tester (product name “DUH-W201”, manufactured by Shimadzu Corporation) to apply a load at a loading rate of 0.28 mN/sec with a Vickers indenter at 160° C., holding a maximum load of 10 mN for 10 seconds, and then unloading at a loading rate of 0.28 mN/sec.

### <Physical Properties of Polymer Film>

The polymer film according to the present disclosure has a moisture absorption rate of 2.5% or less at a temperature of 25° C. and a relative humidity of 80%.

Since the moisture absorption rate is 2.5% or less, moisture is not likely to be accumulated in the polymer film, interlayer peeling is suppressed, and heat resistance is excellent.

From the viewpoint of further improving the heat resistance of the polymer film, the moisture absorption rate is preferably 1.0% or less and more preferably 0.5% or less. The lower limit value of the moisture absorption rate is not particularly limited, and is, for example, 0%.

In the present disclosure, the moisture absorption rate is measured by the following method.

The moisture content can be calculated by conditioning the polymer film at a temperature of 25° C. and a relative humidity of 80% for 24 hours, measuring the moisture content using a moisture content meter, a sample drying device “CA-03” and “VA-05” (manufactured by Mitsubishi Chemical Corporation) by Karl Fischer method, and dividing the moisture content (g) by the sample mass (g, including the moisture content).

### <Method of Manufacturing Polymer Film>

### (Film FORMATION)

A method for manufacturing the polymer film according to the embodiment of the present disclosure is not particularly limited, and a known method can be referred to.

Suitable examples of the film forming method include a co-casting method, a multilayer coating method, and a co-extrusion method. Among these, the film forming method is preferably a co-casting method.

In a case where the multilayer structure in the polymer film is manufactured by the co-casting method or the multilayer coating method, it is preferable that the co-casting method or the multilayer coating method is performed by using a composition for forming the layer A, a composition for forming the layer B, a composition for forming the layer C, or the like obtained by dissolving or dispersing components of each layer, such as the liquid crystal polymer, in a solvent.

Examples of the solvent include halogenated hydrocarbons such as dichloromethane, chloroform, 1,1-dichloroethane, 1,2-dichloroethane, 1,1,2,2-tetrachloroethane, 1-chlorobutane, chlorobenzene, and o-dichlorobenzene; halogenated phenols such as p-chlorophenol, pentachlorophenol, and pentafluorophenol; ethers such as diethyl ether, tetrahydrofuran, and 1,4-dioxane; ketones such as acetone and cyclohexanone; esters such as ethyl acetate and γ-butyrolactone; carbonates such as ethylene carbonate and propylene carbonate; amines such as triethylamine; nitrogen-containing heterocyclic aromatic compounds such as pyridine; nitriles such as acetonitrile and succinonitrile; amides such as N,N-dimethylformamide, N,N-dimethylacetamide, and N-methylpyrrolidone; urea compounds such as tetramethylurea; nitro compounds such as nitromethane and nitrobenzene; sulfur compounds such as dimethyl sulfoxide and sulfolane; and phosphorus compounds such as hexamethylphosphoramide and tri-n-butyl phosphate. Among these, two or more kinds thereof may be used in combination.

From the viewpoint of low corrosiveness and satisfactory handleability, a solvent containing, as a main component, an aprotic compound, particularly an aprotic compound having no halogen atom is preferable as the solvent, and the proportion of the aprotic compound in the entire solvent is preferably 50% by mass to 100% by mass, more preferably 70% by mass to 100% by mass, and particularly preferably 90% by mass to 100% by mass. In addition, from the viewpoint of easily dissolving the liquid crystal polymer, as the above-described aprotic compound, it is preferable to use an amide such as N,N-dimethylformamide, N,N-dimethylacetamide, tetramethylurea, and N-methylpyrrolidone, or an ester such as γ-butyrolactone; and it is more preferable to use N,N-dimethylformamide, N,N-dimethylacetamide, or N-methylpyrrolidone.

In addition, as the solvent, from the viewpoint of easily dissolving the liquid crystal polymer, a solvent containing a compound having a dipole moment of 3 to 5 as a main component is preferable, and the proportion of a compound having a dipole moment of 3 to 5 in the total solvent is preferably 50% by mass to 100% by mass, more preferably 70% by mass to 100% by mass, and particularly preferably 90% by mass to 100% by mass.

It is preferable to use the compound having a dipole moment of 3 to 5 as the above-described aprotic compound.

In addition, as the solvent, from the viewpoint of ease removal, a solvent containing, as a main component, a compound having a boiling point of 220° C. or lower at 1 atm is preferable, and a proportion of the compound having a boiling point of 220° C. or lower at 1 atm in the entire solvent is preferably 50% by mass to 100% by mass, more preferably 70% by mass to 100% by mass, and particularly preferably 90% by mass to 100% by mass.

It is preferable to use the compound having a boiling point of 220° C. or lower at 1 atm as the above-described aprotic compound.

In addition, in the method for manufacturing the polymer film according to the embodiment of the present disclosure, in a case where the polymer film is manufactured by the co-casting method, the multilayer coating method, the co-extrusion method, or the like, a support may be used.

Examples of the support include a metal drum, a metal band, a glass plate, a resin film, and a metal foil. Among these, the support is preferably a metal drum, a metal band, or a resin film.

Examples of the resin film include a polyimide (PI) film, and examples of commercially available products thereof include U-PILEX S and U-PILEX R (manufactured by Ube Corporation), KAPTON (manufactured by Du Pont-Toray Co., Ltd.), and IF30, IF70, and LV300 (manufactured by SKC Kolon PI, Inc.).

In addition, the support may have a surface treatment layer formed on the surface so that the support can be easily peeled off. Hard chrome plating, a fluororesin, or the like can be used as the surface treatment layer.

An average thickness of the resin film support is not particularly limited, but is preferably 25 μm or more and 75 μm or less and more preferably 50 μm or more and 75 μm.

In addition, a method for removing at least a part of the solvent from a cast or applied film-like composition (a coating film) is not particularly limited, and a known drying method can be used.

### (Stretching)

In the polymer film according to the embodiment of the present disclosure, stretching can be combined as appropriate from the viewpoint of controlling molecular alignment and adjusting thermal expansion coefficient and mechanical properties. The stretching method is not particularly limited, and a known method can be referred to, and the stretching method may be carried out in a solvent-containing state or in a dry film state. The stretching in the solvent-containing state may be carried out by gripping and stretching the film, or may be carried out by utilizing self-contraction due to drying without stretching. The stretching is particularly effective for the purpose of improving the breaking elongation and the breaking strength, in a case where brittleness of the film is reduced by addition of an inorganic filler or the like.

### Applications

The polymer film according to the embodiment of the present disclosure can be used for various applications. Among the various applications, the polymer film can be used suitably as a film for an electronic component such as a printed wiring board and more suitably for a flexible printed circuit board.

In addition, the polymer film according to the present disclosure can be suitably used as a liquid crystal polymer film for metal adhesion.

### [Laminate]

It is sufficient that the laminate according to the embodiment of the present disclosure is a laminate including the polymer film according to the embodiment of the present disclosure. The laminate according to the present disclosure preferably includes the polymer film according to the present disclosure and a metal layer or a metal wire disposed on at least one surface of the polymer film, and it is more preferable that the metal layer or the metal wire is a copper layer or a copper wire.

In addition, the laminate according to the present disclosure preferably has the polymer film according to the present disclosure having the layer A and the layer B, and a metal layer or a metal wire disposed on a surface of the polymer film on a layer A side, and it is more preferable that the metal layer or the metal wire is a copper layer or a copper wire.

In addition, the laminate according to the present disclosure preferably has the polymer film according to the present disclosure including the layer B, the layer A, and the layer C in this order, and a metal layer or a metal wire disposed on a surface of the polymer film on a layer C side, and it is more preferable that the metal layer or the metal wire is a copper layer or a copper wire.

In a case where a metal layer or a metal wire is disposed on both surfaces of the polymer film, the two metal layers or metal wires may be metal layers or metal wires having the same material, thickness, and shape, or may be metal layers or metal wires having different materials, thicknesses, and shapes. From the viewpoint of adjusting the characteristic impedance, the two metal layers or metal wires may be metal layers or metal wires having different materials and thicknesses.

The above-described metal layer and metal wire are not particularly limited and may be any known metal layer or metal wire, but for example, a silver layer, a silver wire, a copper layer, or a copper wire is preferable, and a copper layer or a copper wire is more preferable.

Furthermore, from the viewpoint of adjusting the characteristic impedance, preferred examples thereof also include an aspect in which a metal layer is laminated on one side of the layer B or the layer C, and another film (preferably, another polymer film) is laminated on the other side.

A peel strength between the above-described polymer film and the above-described metal layer is preferably 0.5 kN/m or more, more preferably 0.7 kN/m or more, still more preferably 0.7 kN/m to 2.0 kN/m, and particularly preferably 0.9 kN/m to 1.5 kN/m.

In the present disclosure, the peel strength between the polymer film and the metal layer (for example, the copper layer) is measured by the following method.

A peeling test piece with a width of 1.0 cm is produced from the laminate of the polymer film and the metal layer, the film is fixed to a flat plate with double-sided adhesive tape, and the strength (kN/m) in a case of peeling the polymer film off from the metal layer at a rate of 50 mm/min is measured by the 180° method in conformity with JIS C 5016 (1994).

The metal layer is preferably a silver layer or a copper layer, and more preferably a copper layer. As the copper layer, a rolled copper foil formed by a rolling method or an electrolytic copper foil formed by an electrolytic method is preferable.

An average thickness of the metal layer, preferably the copper layer, is not particularly limited, but is preferably 2 μm to 20 μm, more preferably 3 μm to 18 μm, and still more preferably 5 μm to 12 μm. The copper foil may be copper foil with a carrier formed on a support (carrier) so as to be peelable. As the carrier, a known carrier can be used. An average thickness of the carrier is not particularly limited, but is preferably 10 μm to 100 μm and more preferably 18 μm to 50 μm.

From the viewpoint of suppressing the distortion of the metal wire in a case where the film is adhered to the metal wire, it is preferable that a thickness of the layer B is larger than a thickness of the metal layer (for example, the copper layer).

The metal layer in the laminate according to the embodiment of the present disclosure may be a metal layer having a circuit pattern.

It is also preferable that the metal layer in the laminate according to the embodiment of the present disclosure is processed into, for example, a desired circuit pattern by etching to form a flexible printed circuit board. The etching method is not particularly limited, and a known etching method can be used.

### EXAMPLES

Hereinafter, the present disclosure will be described in more detail with reference to Examples. The materials, the used amounts, the proportions, the treatment contents, the treatment procedures, and the like described in the following examples can be appropriately changed without departing from the gist of the present disclosure. Therefore, the scope of the present disclosure is not limited to the following specific examples.

The details of the polymer and the additive (components other than the polymer) used in the production of the layer A, the layer B, and the layer C, and the copper foil are as follows.

### <Polymer>

LC-A: Aromatic polyester amide (liquid crystal polymer) produced according to the following production method
SEBS: styrene-ethylene-butylene-styrene block copolymer, product name “TUFTEC M1913”, manufactured by Asahi Kasei Corporation
SIBS: styrene-isobutylene-styrene block copolymer, product name “SIBSTAR 073T-UL”, manufactured by KANEKA Corporation
PI-A: solution of polyimide precursor produced by the following production method

### —Synthesis of Aromatic Polyester Amide LC-A—

940.9 g (5.0 mol) of 6-hydroxy-2-naphthoic acid, 415.3 g (2.5 mol) of isophthalic acid, 377.9 g (2.5 mol) of acetaminophen, 867.8 g (8.4 mol) of acetic anhydride are put in a reactor comprising a stirring device, a torque meter, a nitrogen gas introduction pipe, a thermometer, and a reflux condenser, gas in the reactor is substituted with nitrogen gas, a temperature increases from a room temperature (23° C., the same applies hereinafter) to 140° C. over 60 minutes while stirring under a nitrogen gas flow, and refluxing is performed at 140° C. for three hours.

Next, the temperature was raised from 150° C. to 300° C. over 5 hours while distilling off by-produced acetic acid and unreacted acetic anhydride, and maintained at 300° C. for 30 minutes. Thereafter, a content is taken out from the reactor and is cooled to the room temperature. The obtained solid was pulverized by a pulverizer to obtain a powdered aromatic polyester amide A1a. A flow start temperature of the aromatic polyester amide A1a was 193° C. In addition, the aromatic polyester amide A1a was a fully aromatic polyester amide.

The aromatic polyester amide A1a was subjected to solid polymerization by increasing the temperature from room temperature to 160° C. over 2 hours and 20 minutes in a nitrogen atmosphere, increasing the temperature from 160° C. to 180° C. over 3 hours and 20 minutes, and maintaining the temperature at 180° C. for 5 hours, and then the resultant was cooled. Next, the resultant was pulverized by a pulverizer to obtain a powdered aromatic polyester amide A1b. A flow start temperature of the aromatic polyester amide A1b was 220° C.

The aromatic polyester amide A1b was subjected to solid polymerization by increasing the temperature from room temperature to 180° C. over 1 hour and 25 minutes in a nitrogen atmosphere, increasing the temperature from 180° C. to 255° C. over 6 hours and 40 minutes, and maintaining the temperature at 255° C. for 5 hours, and then the resultant was cooled, thereby obtaining a powdered aromatic polyester amide LC-A.

The flow start temperature of the aromatic polyester amide LC-A was 302° C. In addition, in a case where a melting point of the aromatic polyester amide LC-A was measured using a differential scanning calorimetry device, the measured value was 311° C. The dielectric loss tangent of aromatic polyester amide LC-A was 0.003.

### —Production of Polyimide Precursor PI-A Solution—

68.74 kg of 3,3′,4,4′-biphenyltetracarboxylic dianhydride (BPDA) and 23.6 kg of para-phenylenediamine (PDA) were added to 850 kg of N,N-dimethylformamide (DMF), and the mixture was stirred and dissolved for 30 minutes in a nitrogen atmosphere to obtain a polymerized substance. The components added so far are non-thermoplastic block components, and the components added thereafter are thermoplastic block components. 14.5 kg of 4,4′-oxydiphthalic acid anhydride (ODPA) was put into the polymerization solution containing the non-thermoplastic block component, 6.8 kg of pyromellitic dianhydride (PMDA) was added thereto, 19.2 kg of 2,2-bis [4-(4-aminophenoxy)phenyl] propane (BAPP) was put thereinto, 17.2 kg of 4,4′-bis(4-aminophenoxy) biphenyl (BAPB) was put thereinto, and the mixture was stirred for 1 hour to obtain a polyamic acid PA-A having a viscosity of 2,500 poise at 23° C.

Acetic anhydride (1.6 mol with respect to 1 mol of the amide acid unit of the polyamic acid PA-A), isoquinoline (0.5 mol with respect to 1 mol of the amide acid unit of the polyamic acid PA-A), and DMF (the total mass of the acetic anhydride, isoquinoline, and DMF was 45% of the polyamic acid PA-A) were added to the polyamic acid PA-A to obtain a polyimide precursor PI-A solution.

### <Additive>

LCP particles: liquid crystal polymer particles produced according to the following production method
SEBS particles: hydrogenated styrene-ethylene-butylene-styrene block copolymer particles, frozen and pulverized product of TUFTEC M1913 manufactured by Asahi Kasei Corporation (average particle diameter: 5.0 μm (D50))·
Curing agent C1: condensed polycyclic epoxy resin, product name “jER YX8800”, manufactured by Mitsubishi Chemical Corporation
Curing agent C2: maleimide, product name “MIR-3000-70MT”, manufactured by Nippon Kayaku Co., Ltd.
Curing agent C3: Aminophenol-type epoxy resin, product name “jER630”, manufactured by Mitsubishi Chemical Corporation
SiO₂ particles: silica particles, product name “SC2500-SPJ”, manufactured by Admatechs Co., Ltd.
Al₂O₃ particles: aluminum hydroxide particles, product name “AO-502”, manufactured by Admatechs Co., Ltd.
BN particles: boron nitride particles, product name “HP40MF100”, manufactured by Mizushima Ferroalloy & Metal Co., Ltd.

### —Production of LCP Particles—

1034.99 g (5.5 mol) of 2-hydroxy-6-naphthoic acid, 89.18 g (0.41 mol) of 2,6-naphthalenedicarboxylic acid, 236.06 g (1.42 mol) of terephthalic acid, 341.39 g (1.83 mol) of 4,4-dihydroxybiphenyl, and potassium acetate and magnesium acetate as a catalyst were put in a reactor including a stirring device, a torque meter, a nitrogen gas introduction pipe, a thermometer, and a reflux condenser. The gas in the reactor was replaced with nitrogen gas, and acetic anhydride (1.08 molar equivalent with respect to a hydroxyl group) was further added thereto. The temperature was raised from room temperature to 150° C. over 15 minutes while stirring in a nitrogen gas stream, and refluxing was performed at 150° C. for 2 hours.

Next, the temperature was raised from 150° C. to 310° C. over 5 hours while distilling off by-produced acetic acid and unreacted acetic anhydride, and a polymerized substance was cooled to room temperature. An obtained polymerized substance increases in temperature from the room temperature to 295° C. over 14 hours, and is subjected to solid polymerization at 295° C. for one hour. After solid polymerization, cooling is performed to the room temperature over five hours, and LCP particles are obtained. The LCP particles have a median diameter (D50) of 7 μm, a dielectric loss tangent of 0.0007, and a melting point of 334° C.

### <Copper Foil>

M1: product name “CF-T9DA-SV-18”, manufactured by Fukuda Metal Foil & Powder Co., Ltd., average thickness: 18 μm
M2: product name “MT18FL”, manufactured by Mitsui Mining & Smelting Co., Ltd., average thickness: 1.5 μm, with carrier copper foil (thickness: 18 μm) [Examples 1 to 14 and Comparative Example 1]

### —Preparation of Solution for Layer C—

8 parts of aromatic polyester amide LC-A was added to 92 parts of N-methylpyrrolidone, and the mixture was stirred at 140° C. for 4 hours in a nitrogen atmosphere to obtain a solution of aromatic polyester amide LC-A (concentration of solid contents: 8% by mass).

A solution of aromatic polyester amide LC-A and additives were mixed so as to have a composition containing the polymer and the additives at the mass ratios shown in Table 1, thereby preparing a solution for a layer C.

### —Preparation of Solution for Layer A—

The solution of aromatic polyester amide LC-A and the additives were mixed so as to obtain a composition containing the polymer and the additives having the mass ratios shown in Table 1, and N-methylpyrrolidone was added thereto to adjust the concentration of solid contents to 25% by mass, thereby obtaining a solution for a layer A.

### —Preparation of Solution for Layer B—

The solution of the aromatic polyester amide LC-A and the additives were mixed so as to have a composition containing the polymer and the additives having the mass ratios shown in Table 1, and N-methylpyrrolidone was added in Examples 1 to 4 and Comparative Example 1, and toluene was added in Examples 5 to 14 so that the concentration of solid contents was adjusted to 20% by mass, thereby obtaining a solution for a layer B.

### Preparation of Single-Sided Copper-Clad Laminated Plate

### Examples 1 to 4 and Comparative Example 1

The obtained solution for a layer C, the solution for a layer A, and the solution for a layer B were fed to a slot die coater equipped with a slide coater, and applied onto the treated surface of the copper foil shown in Table 1 in a three-layer configuration (layer C/layer A/layer B) by adjusting the flow rate so that the thickness after drying was the thickness shown in Table 1. The solvent was removed from the coating film by drying at 40° C. for 4 hours. Further, a heat treatment was performed in which the temperature was raised from room temperature to 300° C. at 1° C./min in a nitrogen atmosphere, and the temperature was maintained at the temperature for 2 hours, thereby obtaining a polymer film (single-sided copper-clad laminated plate) having a copper layer/layer C/layer A/layer B.

### Examples 5 and 14

The obtained solution for a layer C and the solution for a layer A were fed to a slot die coater equipped with a slide coater, and applied onto the treated surface of the copper foil shown in Table 1 in a two-layer configuration (layer C/layer A) by adjusting the flow rate so that the thickness after drying was the thickness shown in Table 1. The solvent was removed from the coating film by drying at 40° C. for 4 hours. The temperature was further raised from room temperature to 300° C. at 1° C./min in a nitrogen atmosphere, and the heat treatment was performed for 2 hours at that temperature to obtain a polymer film having a copper layer (a single-sided copper-clad laminated plate). Furthermore, the layer B solution was fed to a slot die coater, and the coating was performed by adjusting the flow rate such that the thickness after drying was the thickness shown in Table 1. The coating film was dried at 90° C. for 30 minutes to remove the solvent from the coating film, thereby obtaining a polymer film (single-sided copper-clad laminated plate) having a copper layer/layer C/layer A/layer B.

### —Production of Double-Sided Copper-Clad Laminated Plate—

The copper foil and the single-sided copper-clad laminated plate were laminated in this order such that the treated surface of the copper foil shown in Table 1 was in contact with the layer B of the single-sided copper-clad laminated plate. A double-sided copper-clad laminated plate precursor was obtained by performing a laminating treatment for 1 minute under conditions of 140° C. and a laminating pressure of 0.4 MPa using a laminator (product name a thermal compression machine (product name “MP-SNL”, manufactured by Toyo Seiki Seisaku-sho, Ltd.), the obtained double-sided copper-clad laminated plate precursor was thermally compression-bonded for 60 minutes under conditions of 200° C. and 4 MPa to prepare a double-sided copper-clad laminated plate.

### Comparative Example 2

### —Production of Polymer Film—

The polyimide precursor PI-A solution was passed through a sintered fiber metal filter having a nominal pore diameter of 10 μm and further passed through a sintered fiber filter having a nominal pore diameter of 10 μm to obtain a solution for a comparative layer A. Then, the solution for the layer A, the solution for the layer B, and the solution for the layer C for comparative purposes were fed to a casting die equipped with a feed block adjusted for co-casting, and cast on a stainless steel belt (support). After casting, the film was gradually heated in a range of 70° C. to 130° C. and peeled off from the support in a self-supporting gel film state. Subsequently, the polymer film was obtained by stepwise heating in a nitrogen atmosphere while gripping with a pin tenter. The heating temperature at this time was set to 250° C. to 350° C.

### —Preparation of Single-Sided Copper-Clad Laminated Plate—

The treated surface of the copper foil shown in Table 1 was disposed on one surface of the obtained polymer film so as to be in contact with the polymer film, and a precursor of a single-sided copper-clad laminated plate was obtained by performing a laminating treatment for 1 minute under conditions of 140° C. and a laminating pressure of 0.4 MPa using a laminator (“Vacuum Laminator V-130” manufactured by Nikko-Materials Co., Ltd.). Subsequently, using a thermocompression machine (“MP-SNL” manufactured by Toyo Seiki Seisaku-sho, Ltd.), the obtained single-sided copper-clad laminated plate precursor was subjected to thermocompression under conditions of 300° C. and 4.5 MPa for 10 minutes to prepare a double-sided copper-clad laminated plate.

### —Production of Double-Sided Copper-Clad Laminated Plate—

The copper foil and the single-sided copper-clad laminated plate were laminated in this order such that the treated surface of the copper foil shown in Table 1 was in contact with the layer B of the single-sided copper-clad laminated plate. A double-sided copper-clad laminated plate precursor was obtained by performing a laminating treatment for 1 minute under conditions of 140° C. and a laminating pressure of 0.4 MPa using a laminator (product name a thermal compression machine (product name “MP-SNL”, manufactured by Toyo Seiki Seisaku-sho, Ltd.), the obtained double-sided copper-clad laminated plate precursor was thermally compression-bonded for 60 minutes under conditions of 300° C. and 4 MPa to prepare a double-sided copper-clad laminated plate.

Using the obtained double-sided copper-clad laminated plate or single-sided copper-clad laminated plate, the moisture permeability of the layer A and the layer B at a temperature of 80° C. and a relative humidity of 90%, the moisture absorption rate of the polymer film at a temperature of 25° C. and a relative humidity of 80%, and the dielectric loss tangent of the polymer film were measured. The measuring methods were as follows.

### <Dielectric Loss Tangent>

The dielectric loss tangent of the polymer film was measured using a polymer film obtained by removing a copper foil of a double-sided copper-clad laminated plate with an aqueous solution of ferric chloride, washing the copper foil with pure water, and drying the copper foil.

The dielectric loss tangent was measured by a resonance perturbation method at a frequency of 10 GHz. A 10 GHz cavity resonator (“CP531” manufactured by Kanto Electronic Application & Development Inc.) was connected to a network analyzer (“E8363B” manufactured by Agilent Technology Co., Ltd.), a polymer film was inserted into the cavity resonator, and the dielectric loss tangent of the polymer film was measured from a change in resonance frequency before and after the insertion for 96 hours in an environment of a temperature of 25° C. and a humidity of 60% RH.

### <Moisture Absorption Rate>

The moisture absorption rate of the entire polymer film was measured using a polymer film obtained by removing the copper foil of the double-sided copper-clad laminated plate with an aqueous solution of ferric chloride, washing the copper foil with pure water, and drying the copper foil.

The polymer film was conditioned at a temperature of 25° C. and a relative humidity of 80% for 24 hours, and then measured by a Karl Fischer method with a moisture content meter and a sample drying device “CA-03” and “VA-05” (manufactured by Mitsubishi Chemical Corporation), and the moisture content (g) was calculated by dividing the moisture content (g) by the sample mass (g, including the moisture content).

### <Moisture Permeability>

The moisture permeability of each layer was measured by the following method. First, one copper foil of the double-sided copper-clad laminated plate is removed with an aqueous solution of ferric chloride, washed with pure water, and then scraped off with a razor. The other copper foil was removed with an aqueous solution of ferric chloride and washed with pure water. The moisture permeability of each layer was measured using the portion obtained by drying.

With reference to a moisture permeability test (cup method) of JIS Z 0208:1976, the film was set in a moisture permeation cup having an inner diameter of 20 mmφ containing calcium chloride, and a mass change before and after being placed in a constant temperature and humidity device at a temperature of 80° C. and a relative humidity of 90% for 24 hours was multiplied by the measured film thickness and divided by 50 to calculate a moisture permeability in terms of a film thickness of 50 μm.

Using the obtained double-sided copper-clad laminated plate or single-sided copper-clad laminated plate, the step followability and the heat resistance were evaluated. The evaluation method was as follows.

### <Step Followability>

—Production of Base Material A with Wiring Patterns—

A copper foil (product name “CF-T9DA-SV-18”, average thickness of 18 μm, manufactured by Fukuda Metal Foil & Powder Co., Ltd.) and a liquid crystal polymer film (product name “CTQ-50”, average thickness of 50 μm, manufactured by Kuraray Co., Ltd.) as a base material were produced. The copper foil, the base material, and the copper foil were laminated in this order such that the treated surface of the copper foil was in contact with the base material. A double-sided copper-clad laminated plate precursor was obtained by performing a laminating treatment for 1 minute under conditions of 140° C. and a laminating pressure of 0.4 MPa using a laminator (product name “Vacuum Laminator V-130”, manufactured by Nikko-Materials Co., Ltd.). Subsequently, using a thermal compression machine (product name “MP-SNL”, manufactured by Toyo Seiki Seisaku-sho, Ltd.), the obtained double-sided copper-clad laminated plate precursor was thermally compression-bonded for 10 minutes under conditions of 300° C. and 4.5 MPa to prepare a double-sided copper-clad laminated plate.

The copper foils on both surfaces of the above-described double-sided copper-clad laminated plate were roughened, and a dry film resist was bonded thereto. The exposure and development were performed such that the wiring patterns remained, etching was performed, and the dry film was further removed to produce a base material with wiring patterns in which the line/space including the ground line and the three pairs of signal lines on both sides of the base material was 100 μm/100 μm. A length of the signal line was 50 mm, and a width of the signal line was set such that characteristic impedance was 50Ω.

—Production of Base Material B with Wiring Pattern—

A copper foil (product name “MT18FL”, average thickness: 1.5 μm, with carrier copper foil (thickness: 18 μm), manufactured by Mitsui Mining & Smelting Co., Ltd.) and a liquid crystal polymer film (product name “CTQ-50”, average thickness: 50 μm, manufactured by Kuraray Co., Ltd.) as a base material were produced. The copper foil and the base material were superimposed so that the treated surface of the copper foil was in contact with the base material. A single-sided copper-clad laminated plate precursor was obtained by performing a laminating treatment for 1 minute under conditions of 140° C. and a laminating pressure of 0.4 MPa using a laminator (product name “Vacuum Laminator V-130”, manufactured by Nikko-Materials Co., Ltd.). Subsequently, using a thermal compression machine (product name “MP-SNL”, manufactured by Toyo Seiki Seisaku-sho, Ltd.), the obtained precursor of the single-sided copper-clad laminated plate was thermally compression-bonded for 10 minutes under the conditions of 300° C. and 4.5 MPa to prepare a single-sided copper-clad laminated plate. The carrier copper foil in the single-sided copper-clad laminated plate was peeled off, the exposed 1.5 μm copper foil was roughened, and a dry film resist was bonded. The wiring pattern was exposed and developed, and a plating treatment was performed on a region where the resist pattern was not disposed. Further, the dry film resist was peeled off, and copper exposed in the peeling step was removed by flash etching to produce a base material with wiring patterns having a line/space of 20 μm/20 μm.

### —Production of Wiring Board—

A wiring board was produced using the produced single-sided copper-clad laminated plate by the following method.

The produced base material with a wiring pattern was superimposed on the layer B side of the single-sided copper-clad laminated plate, and subjected to a heat press for 1 hour under the conditions of 160° C. and 4 MPa to obtain a wiring board.

A wiring pattern (ground line and signal line) is embedded in the obtained wiring board. In a case where the substrate A with a wiring pattern was used, the thickness of the wiring pattern was 18 μm, and in a case where the substrate B with a wiring pattern was used, the thickness of the wiring pattern was 12 μm.

The wiring board was cut along the thickness direction with a microtome, and a cross section was observed with an optical microscope. The length L of the gap generated in the in-plane direction between the layer B and the wiring pattern was measured. The average value at 10 locations was calculated and used as an index for evaluating the step followability. The evaluation standards are as follows.
A: Lis less than 1 μm.
B: Lis 1 μm or more and less than 3 μm.
C: Lis 3 μm or more.

### <Heat Resistance>

The prepared double-sided copper-clad laminated plate was cut out to a size of 30 mm×30 mm and used as an evaluation sample. The evaluation sample was treated in a constant temperature and humidity tank at a temperature of 85° C. and a relative humidity of 85% for 168 hours. Thereafter, the evaluation sample was placed in an oven set to 260° C. and heated for 15 minutes. The evaluation sample after heating was cut with a razor, and the cross section was observed with an optical microscope to evaluate the peeling state.
A: No peeling was observed.
B: Peeling was recognized with a width of 1 mm or less.
C: peeling was recognized in a width of more than 1 mm.

The evaluation results are shown in Table 1. In Table 1, the moisture permeability means a moisture permeability at a temperature of 80° C. and a relative humidity of 90%, and the unit thereof is “g/(m²·day)”. The moisture absorption rate means a moisture absorption rate at a temperature of 25° C. and a relative humidity of 80%, and the unit thereof is “%”. The “elastic modulus ratio of layer A/layer B” means a ratio of the elastic modulus of the layer A at 160° C. to the elastic modulus of the layer B at 160° C. A pattern in a case where a wiring board was produced using the base material A with a wiring pattern, and the step followability was evaluated was referred to as “Pattern A”, and a pattern in a case where a wiring board was produced using the base material B with a wiring pattern, and the step followability was evaluated was referred to as “Pattern B”.

TABLE 1

| | | Layer A | | | | | | Layer B | | | | | |
|---|---|---|---|---|---|---|---|---|---|---|---|---|---|
| | | Polymer | | Additive | | | | Polymer | | Additive 1 | | Additive 2 | |
| | | | Conte [symbol] | | Content | | Moisture | | Content | | Content | | Content |
| | Foil | | (% by | | (% by | Thickness | perme- | | (% by | | (% by | | (% by |
| | Kind | Kind | mass) | Kind | mass) | (μm) | ability | Kind | mass) | Kind | mass) | Kind | mass) |
| Comparative | M1 | LC-A | 100 | — | — | 25 | 6.2 | LC-A | 20 | SEBS | 80 | — | — |
| Example 1 | | | | | | | | | | particles | | | |
| Comparative | M1 | PI-A | 100 | — | — | [symbol] | 2 [symbol] 0 | LC-A | 100 | — | — | — | — |
| Example 2 | | | | | | | | | | | | | |
| Example 1 | M1 | LC-A | 100 | LCP | | 25 | 6.2 | LC-A | 40 | SEBS | [symbol] 0 | — | — |
| | | | | particles | | | | | | particles | | | |
| Example 2 | M1 | LC-A | 25 | LCP | 75 | 25 | 0.5 | LC-A | 40 | SEBS | [symbol] 0 | — | — |
| | | | | particles | | | | | | particles | | | |
| Example 3 | M1 | LC-A | 25 | LCP | 75 | 25 | 0. [symbol] | LC-A | 80 | SEBS | 20 | — | — |
| | | | | particles | | | | | | particles | | | |
| Example 4 | M2 | LC-A | 25 | LCP | 75 | [symbol] | 0.5 | LC-A | [symbol] 0 | SEBS | 20 | — | — |
| | | | | particles | | | | | | particles | | | |
| Example 5 | M1 | LC-A | 25 | LCP | 75 | 20 | 0.5 | SEBS | [symbol] 0 | Curing | 40 | — | — |
| | | | | particles | | | | | | agent C1 | | | |
| Example 6 | M1 | LC-A | 25 | LCP | 75 | 25 | 0.5 | SEBS | 60 | LCP | 40 | — | — |
| | | | | particles | | | | | | particles | | | |
| Example [symbol] | M1 | LC-A | 25 | LCP | 75 | 25 | 0.5 | SEBS | 60 | LCP | 20 | Curing | 20 |
| | | | | particles | | | | | | particles | | agent C1 | |
| Example 8 | M1 | LC-A | 25 | LCP | 75 | [symbol] | 0.5 | SEBS | 60 | LCP | 20 | BN | 20 |
| | | | | particles | | | | | | particles | | particles | |
| Example 9 | M1 | LC-A | 25 | LCP | 75 | 25 | 0.5 | SEBS | 70 | Curing | 30 | — | — |
| | | | | particles | | | | | | agent C1 | | | |
| Example 10 | M1 | LC-A | 25 | LCP | 75 | 25 | 0.5 | SEBS | 70 | Curing | [symbol] 0 | — | — |
| | | | | particles | | | | | | agent C2 | | | |
| Example 11 | M1 | LC-A | 25 | LCP | 75 | 25 | 0.5 | SEBS | 51 | SiO [symbol] | 49 | — | — |
| | | | | particles | | | | | | particles | | | |
| Example 12 | M1 | LC-A | 25 | LCP | 75 | 25 | 0.5 | SEBS | 51 | Al₂O₃ | 49 | — | — |
| | | | | particles | | | | | | particles | | | |
| Example 13 | M1 | LC-A | 25 | LCP | 75 | 25 | 0.5 | SEBS | 51 | BN | 49 | — | — |
| | | | | particles | | | | | | particles | | | |
| Example 14 | M1 | LC-A | 25 | LCP | 75 | 25 | 0.5 | SIBS | 100 | — | — | — | — |
| | | | | particles | | | | | | | | | |

| | | | Layer C | | | | | | Elastic | | Evaluation | | |
|---|---|---|---|---|---|---|---|---|---|---|---|---|---|
| | Layer B | | Polymer | | Additive | | | Moisture | [symbol] | | Step | | |
| | Thick- | Moisture | | Content | | Content | Thick- | absorp- | ratio of | Dielectric | followability | | Heat |
| | ness | perme- | | (% by | | (% by | ness | tion | layer | loss | Pattern | Pattern | resis- |
| | (μm) | ability | Kind | mass) | Kind | mass) | (μm) | rate | A [symbol] er B | tangent | A | B | tance |
| Comparative | 25 | 560 | LC-A | 99.6 | Curing | 0.4 | 3 | 0.3 | 475 | 0. [symbol] | A | — | C |
| Example 1 | | | | | agent C3 | | | | | | | | |
| Comparative | [symbol] | 6.2 | LC-A | 100 | — | — | 3 | 2.7 | 3 | 0.010 | C | — | C |
| Example 2 | | | | | | | | | | | | | |
| Example 1 | 25 | 450 | LC-A | 99.6 | Curing | 0.4 | 3 | 0. [symbol] | 345 | 0.00 [symbol] | A | — | B |
| | | | | | agent C3 | | | | | | | | |
| Example 2 | 25 | 450 | LC-A | 99.6 | Curing | 0.4 | 3 | 0.2 | 2 [symbol] | 0.00 [symbol] | A | — | B |
| | | | | | agent C3 | | | | | | | | |
| Example 3 | 25 | 147 | LC-A | 99.6 | Curing | 0.4 | 3 | 0.4 | 257 | 0.00 [symbol] | A | A | A |
| | | | | | agent C3 | | | | | | | | |
| Example 4 | 25 | 147 | LC-A | 99.6 | Curing | 0.4 | 3 | 0.4 | 257 | 0.00 [symbol] | A | A | A |
| | | | | | agent C3 | | | | | | | | |
| Example 5 | 30 | 220 | LC-A | 99.6 | Curing | 0.4 | 3 | 1. [symbol] | 151 | 0.00 [symbol] | B | — | B |
| | | | | | agent C3 | | | | | | | | |
| Example 6 | 25 | 450 | LC-A | 99.6 | Curing | 0.4 | 3 | 0.2 | 128 | 0.00 [symbol] | A | — | B |
| | | | | | agent C3 | | | | | | | | |
| Example [symbol] | 25 | 290 | LC-A | 99.6 | Curing | 0.4 | 3 | 0.2 | 154 | 0.00 [symbol] | A | — | A |
| | | | | | agent C3 | | | | | | | | |
| Example 8 | 25 | 280 | LC-A | 99.6 | Curing | 0.4 | 3 | 0.2 | 148 | 0.00 [symbol] | A | — | A |
| | | | | | agent C3 | | | | | | | | |
| Example 9 | 25 | 250 | LC-A | 99.6 | Curing | 0.4 | 3 | 0.5 | 19 [symbol] | 0.00 [symbol] | A | — | A |
| | | | | | agent C3 | | | | | | | | |
| Example 10 | 25 | 250 | LC-A | 99.6 | Curing | 0.4 | 3 | 0.5 | 19 [symbol] | 0.00 [symbol] | A | — | A |
| | | | | | agent C3 | | | | | | | | |
| Example 11 | 25 | 280 | LC-A | 99.6 | Curing | 0.4 | 3 | 0.3 | 24 [symbol] | 0.00 [symbol] | A | — | A |
| | | | | | agent C3 | | | | | | | | |
| Example 12 | 25 | 270 | LC-A | 99.6 | Curing | 0.4 | 3 | 0.3 | 22 [symbol] | 0.00 [symbol] | A | — | A |
| | | | | | agent C3 | | | | | | | | |
| Example 13 | 25 | 150 | LC-A | 99.6 | Curing | 0.4 | 3 | 0.3 | 20 [symbol] | 0.00 [symbol] | A | — | A |
| | | | | | agent C3 | | | | | | | | |
| Example 14 | 25 | 120 | LC-A | 99.6 | Curing | 0.4 | 3 | 0.2 | 385 | 0.00 [symbol] | A | — | A |
| | | | | | agent C3 | | | | | | | | |

[symbol]

indicates data missing or illegible when filed

As shown in Table 1, in Examples 1 to 14, it was found that, since the layer A and the layer B provided on at least one surface of the layer A were included, the layer A contained a polymer having a dielectric loss tangent of 0.01 or less, the layer B had a moisture permeability of less than 560 g/(m²·day) at a temperature of 80° C. and a relative humidity of 90%, and the layer B had a moisture absorption rate of 2.5% or less at a temperature of 25° C. and a relative humidity of 80%, the step followability and the heat resistance were excellent.

On the other hand, in Comparative Example 1, it was found that the moisture permeability of the layer B at a temperature of 80° C. and a relative humidity of 90% was 560 g/(m²·day) or more, and the heat resistance was inferior.

In Comparative Example 2, it was found that since the moisture absorption rate at a temperature of 25° C. and a relative humidity of 80% was more than 2.5%, the heat resistance was inferior.

The disclosure of Japanese Patent Application No. 2022-175011 filed on Oct. 31, 2022 is incorporated in the present specification by reference. In addition, all documents, patent applications, and technical standards described in the present specification are herein incorporated by reference to the same extent that each individual document, patent application, or technical standard was specifically and individually indicated to be incorporated by reference.

What is claimed is:

1. A polymer film comprising:
a layer A; and
a layer B provided on at least one surface of the layer A,
wherein the layer A contains a polymer having a dielectric loss tangent of 0.01 or less,
the layer B has a moisture permeability of less than 560 g/(m²·day) at a temperature of 80° C. and a relative humidity of 90%, and
the layer B has a moisture absorption rate of 2.5% or less at a temperature of 25° C. and a relative humidity of 80%.

2. The polymer film according to claim 1,
wherein the layer B has a moisture permeability of 300 g/(m²·day) or less at a temperature of 80° C. and a relative humidity of 90%.

3. The polymer film according to claim 1,
wherein the polymer film has a moisture absorption rate of 1.0% or less.

4. The polymer film according to claim 1,
wherein the polymer having a dielectric loss tangent of 0.01 or less is a liquid crystal polymer.

5. The polymer film according to claim 4,
wherein the liquid crystal polymer contains an aromatic polyester amide.

6. The polymer film according to claim 1,
wherein the layer B contains a polymer having a dielectric loss tangent of 0.01 or less.

7. The polymer film according to claim 6,
wherein the polymer having a dielectric loss tangent of 0.01 or less contains a liquid crystal polymer.

8. The polymer film according to claim 7,
wherein the liquid crystal polymer contains an aromatic polyester amide.

9. The polymer film according to claim 1,
wherein the layer B contains a thermoplastic resin containing a constitutional unit based on a monomer having an aromatic hydrocarbon group.

10. The polymer film according to claim 1,
wherein the layer B contains a curing agent.

11. The polymer film according to claim 10,
wherein the curing agent is a compound having at least one functional group selected from the group consisting of an epoxy group and a maleimide group.

12. The polymer film according to claim 9,
wherein the layer B contains an inorganic filler.

13. The polymer film according to claim 12,
wherein the inorganic filler is at least one selected from the group consisting of silica, aluminum hydroxide, and boron nitride.

14. The polymer film according to claim 1, further comprising:
a layer C,
wherein the layer B, the layer A, and the layer C are provided in this order.

15. The polymer film according to claim 1,
wherein a ratio of an elastic modulus of the layer A at 160° C. to an elastic modulus of the layer B at 160° C. is 1.2 or more.

16. A laminate comprising:
the polymer film according to claim 1; and
a metal layer or a metal wire, disposed on at least one surface of the polymer film.
